(19) United States
(12) Patent Application Publication
(10) Pub. No.: US 2021/0171050 A1
(43) Pub. Date: Jun. 10, 2021

(54) SYSTEM FOR EVALUATING VEHICLE PERFORMANCE

(71) Applicants: Hyundai Motor Company, Seoul (KR); Kia Motors Corporation, Seoul (KR)

(72) Inventors: Wook Hyun Han, Seoul (KR); Kee Young Yang, Hwaseong (KR); Il Dong Moon, Seoul (KR)

(21) Appl. No.: 16/995,112

(22) Filed: Aug. 17, 2020

(30) Foreign Application Priority Data
Dec. 10, 2019 (KR) 10-2019-0163960

(51) Int. Cl. B60W 50/04; G01M 17/02; G01M 17/04; G06N 5/02; B60W 40/13; B60W 40/101

(52) U.S. Cl. CPC B60W 50/04; G01M 17/02; G01M 17/04; G06N 5/02; B60W 40/13; B60W 40/101; B60W 2420/40; B60W 2520/26; B60W 2510/22; B60W 2552/00; B60W 2420/42; B60W 2420/52; B60W 2040/1315

(57) ABSTRACT

A system is provided for evaluating vehicle performance. The system includes a function system model that models an operation of a function system of a vehicle and an operation of which is determined based on a control signal output from a controller within the vehicle. Additionally, the system includes a dynamic model configured to model a behavior of the vehicle based on the operation of the function system model.

### CROSS-REFERENCE TO RELATED APPLICATION

This application claims the priority benefit of Korean Patent Application No. 10-2019-0163960, filed Dec. 10, 2019, the disclosure of which is incorporated herein by reference.

### BACKGROUND

### 1. Field of the Disclosure

The present disclosure relates to a system for evaluating vehicle performance, and more particularly, to a system for evaluating vehicle performance for analyzing a behavior of a vehicle based on a reaction of each system by coupling a vehicle system model and a vehicle dynamic model.

### 2. Description of the Related Art

In the vehicle development stage, a document template for recording the specification and performance relevant measurement value of a system has been used for each system to examine the performance of a vehicle that is currently developed. Only a measurement value related to performance is stated in the document template, and thus, it is not possible to evaluate developing vehicle performance for each vehicle system and behavior characteristics of a vehicle based on the performance.

For example, only brake torque is derived using a calculation dependent upon an application for providing a document template when brake performance of a vehicle is evaluated. However, to evaluate brake performance of an actual vehicle, various factors such as a time point of generating torque or energy consumption need to be examined and to then predict an active behavior of a vehicle. In other words, conventionally, when brake performance is evaluated, only brake torque is recognized as a brake performance evaluation factor using a document template, and thus, it is possible to predict deceleration of a vehicle, but it is not possible to determine a behavior that occurs while the vehicle actually brakes, for example, a left/right pull in an actual vehicle.

Accordingly, conventionally, a vehicle including a designed brake is actually manufactured, and then, vehicle performance is evaluated by recognizing a behavior of the vehicle using a trial-error method through direct test driving. Such a conventional method of evaluating vehicle performance requires manufacture of an actual vehicle and incurs the excessive time and cost due to much labor mobilization. In particular, recently, as the number of various controllers used in a vehicle has increased, more time and cost are wasted when a test through an actual vehicle is performed for each controller.

The contents described as the related art have been provided only to assist in understanding the background of the present disclosure and should not be considered as corresponding to the related art known to those having ordinary skill in the art.

### SUMMARY

Therefore, the present disclosure provides a system for evaluating vehicle performance for analyzing a behavior of a vehicle based on a reaction of each system by coupling a vehicle system model and a vehicle dynamic model.

In accordance with an aspect of the present disclosure, the above and other objects may be accomplished by the provision of a system for evaluating vehicle performance including a function system model configured to model an operation of a function system of a vehicle, an operation of which is determined based on a control signal output from a controller within the vehicle, and a dynamic model configured to model a behavior of the vehicle based on the operation of the function system model.

The system for evaluating vehicle performance may further include a controller model configured to model a controller configured to output a control signal for operating the function system based on a detection value output from a sensor mounted within the vehicle, wherein the control signal output from the controller model may be provided as an input of the function system model. The system may further include a sensor model configured to model a sensor mounted within the vehicle and to output a detection value obtained by detecting information related to a driving environment of the vehicle and a driving state of the vehicle. The detection value output from the sensor model may be provided as an input of the controller model. The system may also include a driving environment model configured to model and provide various scenarios for a driving environment of the vehicle. The scenario provided by the driving environment model may be provided as an input of the sensor model.

The dynamic model may include a dynamic load movement model configured to model dynamic load movement characteristics of the vehicle, which is determined according to information including at least some of the weight, center distance, axle weight, and the center of weight of the vehicle and operation relevant information of a vehicle system, input from the function system model, a tire slip model configured to model slip characteristics of a tire based on the dynamic load movement characteristics of the vehicle, and a suspension model configured to model characteristics of a spring or damper based on the dynamic load movement characteristics and hard point characteristics (bump-toe) of a suspension.

The controller model may be configured based on control logic of a controller applied to an actual vehicle, or may be configured in a neural network circuit trained through machine learning based on an input and output signal of an actual vehicle. The sensor model may include a recognition sensor model configured to output information to be acquired by detecting the driving environment of the vehicle, and a vehicle behavior sensor model configured to detect and output information related to the behavior of the vehicle. The sensor model may receive the information related to the behavior of the vehicle and may be configured to provide a detection value detected from the information related to the behavior of the vehicle to the controller model.

In accordance with another aspect of the present disclosure, a system for evaluating vehicle performance for copying a behavior of an actual vehicle may include a driving environment model configured to model and provide various scenarios for a driving environment of a vehicle, a sensor model configured to model a sensor included in the actual vehicle and to output a detection value obtained by detecting information related to the driving environment of the vehicle, provided by the driving environment model, a controller model configured to model a controller included in the actual vehicle and to output a control signal for operating a function system included in the vehicle based on the detection value provided by the sensor model, a function system model configured to model the function system included in the actual vehicle and to provide information regarding an output of the function system of the vehicle, an operation of which is determined based on the control signal output from the controller model, and a dynamic model configured to derive vehicle behavior information based on the output provided from the function system model.

The sensor model may be configured to receive vehicle behavior information derived by the dynamic model and may be configured to provide a detection value obtained by detecting information related to driving characteristics of the vehicle based on the vehicle behavior information to the controller model. The dynamic model may include a dynamic load movement model configured to model dynamic load movement characteristics of the vehicle, which is determined according to information including at least some of the weight, center distance, axle weight, and the center of weight of the vehicle and operation relevant information of a vehicle system, input from the function system model, a tire slip model configured to model slip characteristics of a vehicle tire based on the dynamic load movement characteristics of the vehicle, and a suspension model configured to model characteristics of a spring or damper based on the dynamic load movement characteristics of the vehicle and hard point characteristics (bump-toe) of a suspension.

The controller model may be configured according to control logic of a controller applied to an actual vehicle, or may be configured in a neural network circuit trained through machine learning based on an input and output signal of an actual vehicle. The sensor model may include a recognition sensor model configured to output information to be acquired by detecting the driving environment of the vehicle, and a vehicle behavior sensor model configured to detect and output information related to the behavior of the vehicle.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a block diagram of a system for evaluating vehicle performance according to an exemplary embodiment of the present disclosure;

FIG. 2 is a diagram illustrating an example of a function system model of a system for evaluating vehicle performance according to an exemplary embodiment of the present disclosure;

FIG. 3 is a diagram illustrating a dynamic model of a system for evaluating vehicle performance according to an exemplary embodiment of the present disclosure;

FIG. 4 is a diagram illustrating an example of a controller model of a system for evaluating vehicle performance according to an exemplary embodiment of the present disclosure;

FIG. 5 is a diagram illustrating an example of a sensor model of a system for evaluating vehicle performance according to an exemplary embodiment of the present disclosure; and

FIG. 6 is a diagram illustrating an example of a driving environment model of a system for evaluating vehicle performance according to an exemplary embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles and other alternative fuel vehicles (e.g. fuels derived from resources other than petroleum).

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present disclosure may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, a system for evaluating vehicle performance according to various exemplary embodiments of the present disclosure will be described with reference to the accompanying drawings.

A system for evaluating vehicle performance according to an exemplary embodiment of the present disclosure may be a system for copying a behavior that occurs in an actual vehicle by modeling an actual vehicle in a plurality of models and transferring a signal between the models.

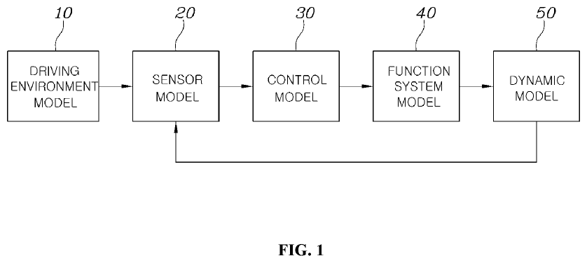

FIG. 1 is a block diagram of a system for evaluating vehicle performance according to an exemplary embodiment of the present disclosure. Notably, the models described herein below may be executed by a controller specifically programmed to execute the processes. Referring to FIG. 1, the system may include a function system model 40 configured to model an operation of a function system of a vehicle, an operation of which is determined based on a control signal output from a controller within the vehicle, and a dynamic model 50 configured to model a behavior of the vehicle based on the operation of the function system model 40.

In addition, the system may further include a controller model 30 configured to model a controller configured to output a control signal for operating the function system based on a detection value output from a sensor included in the vehicle. The control signal output from the controller model 30 may be provided as an input of the function system model 40.

The system may further include a sensor model 20 configured to model a sensor configured to output a detection value obtained by detecting information related to a driving environment of the vehicle. The detection value output from the sensor model 20 may be provided as an input of the controller model 30.

Additionally, the system may include a driving environment model 10 configured to model and provide various scenarios for a driving environment of a vehicle, and the scenario provided by the driving environment model 10 may be provided as an input of the sensor model 20. The function system model 40 may be configured to model a system for embodying various functions provided in a vehicle and may include various models configured to model, for example, a brake system, a steering system, or a driving system. The function system model 40 may provide an output of a system for each function that is performed in response to receiving a control signal from a specific controller in the vehicle.

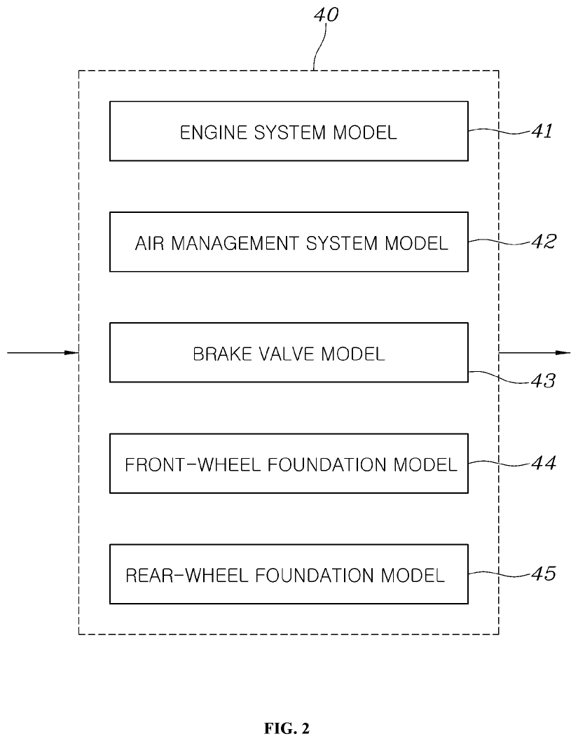

FIG. 2 is a diagram illustrating an example of a function system model of a system for evaluating vehicle performance according to an exemplary embodiment of the present disclosure, and in more detail, illustrates an example of a brake system model of a vehicle.

Referring to FIG. 2, a brake system model 40 as an example of the function system model 40 may include various sub models 41 to 45 configured to operate brake control based on a signal input from a controller (e.g., an anti-lock braking system (ABS) controller) for decelerating the vehicle. The control signal output from the ABS controller may be a signal for determining a brake pressure of each wheel, and a sub model related to various components in the vehicle, which are operated based on the controller signal, may include an engine system model 41 for performing an engine throttle relevant operation based on a brake pressure of each wheel, an air management system model 42 for performing an auxiliary brake and air tank relevant operation based on a brake pressure of each wheel, a brake valve model 43 for adjusting a brake pressure based on a brake pressure of each wheel, and a front-wheel foundation model 44 and a rear-wheel foundation model 45, which are related to an operation of front-wheel foundation and rear-wheel foundation based on a brake pressure of each wheel.

The dynamic model 50 may be configured to model a behavior of an actual vehicle based on an output of a system for each vehicle function, which is output from the function system model 40, and may be a model for outputting a behavior of an actual vehicle when the vehicle brakes (e.g., decelerates) or turns by applying the dynamic load, tire characteristics, suspension hard point characteristics, spring/damper characteristics, wheel alignment characteristic, and the like of the vehicle. The dynamic model 50 may perform animation to visually describe a driving figure of an actual vehicle.

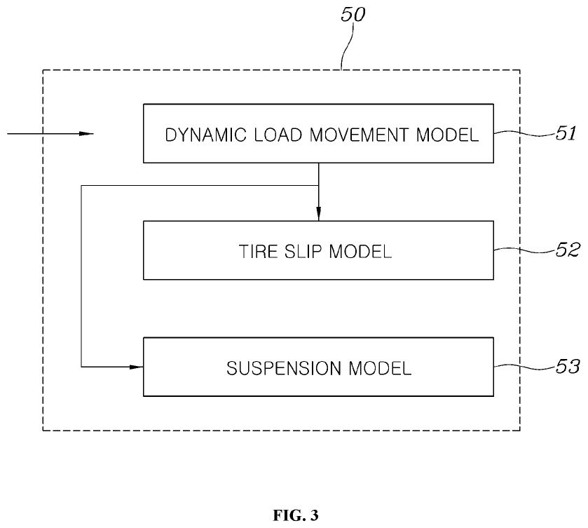

FIG. 3 is a diagram illustrating a dynamic model of a system for evaluating vehicle performance according to an exemplary embodiment of the present disclosure.

Referring to FIG. 3, the dynamic model 50 may include a dynamic load movement model 51 configured to model the dynamic load movement characteristics of a vehicle, determined based on information such as the weight, center distance, axle weight, and the center of weight of the vehicle and operation relevant information of a vehicle system, input from the function system model 40, a tire slip model 52 configured to model the slip characteristics of a vehicle tire based on the dynamic load movement characteristics of the vehicle, and a suspension model 53 configured to model characteristics of a spring or damper based on the dynamic load movement characteristics of the vehicle and the hard point characteristics (bump-toe) of a suspension. The dynamic model 50 may model a behavior of the vehicle based on the dynamic load movement characteristics determined by a dynamic load movement model 51 of the vehicle, slip characteristics determined by the tire slip model 52 based thereon, and suspension characteristics determined by the suspension model 53.

Feedback control may be enabled by providing the vehicle behavior characteristics derived by the dynamic model 50 to the sensor model 20 and outputting a detection value based on the vehicle behavior by the sensor model 20. The controller model 30 may model various controllers mounted within the vehicle and may model various controllers mounted within an actual vehicle, for example, an anti-lock brake system (ABS) controller, a smart cruise control (SCC) controller, a lane keeping assist system (LKAS) controller, an engine controller, or a transmission controller to output a control signal output from an actual controller.

The controller model 30 may be configured according to control logic provided from a manufacturer of the controller. When the manufacturer of the controller does not disclose the control logic, the controller model 30 may also be manufactured through machine learning using a neural network circuit based on an input and output of the controller.

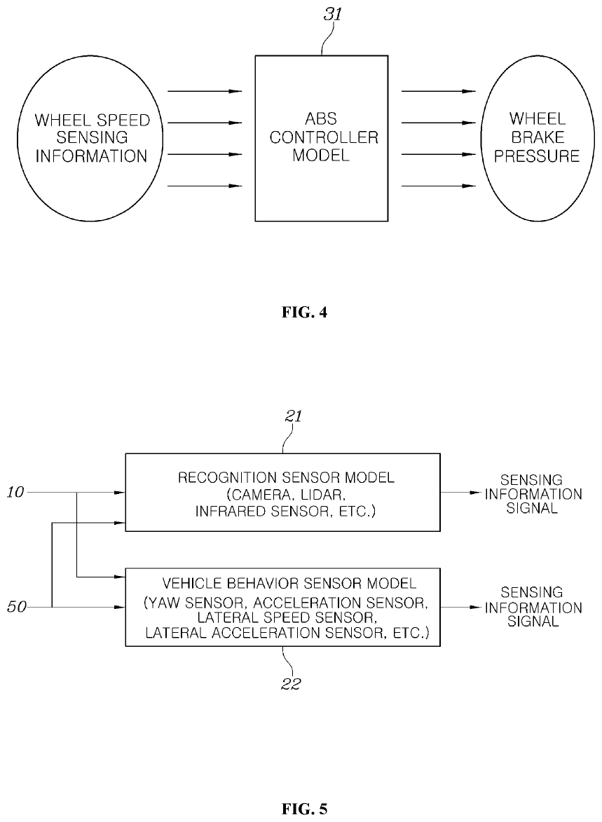

FIG. 4 is a diagram illustrating an example of a controller model of a system for evaluating vehicle performance according to an exemplary embodiment of the present disclosure, and particularly, illustrates an example of an ABS controller model.

As shown in FIG. 4, as an example of the controller model of the system for evaluating vehicle performance according to an exemplary embodiment of the present disclosure, the ABS controller model 30 may receive various wheel speed information from wheel speed sensors mounted within wheels of the vehicle, respectively, and may be modeled to output a control signal for determining a brake pressure of a brake mounted within each wheel of the vehicle based on the received wheel speed information.

Additionally, ABS manufacturers do not disclose detailed ABS control logic as their know-how, and thus, the ABS controller model 30 may be embodied as a neural network circuit modeled to output a similar control signal to an actual ABS controller using machined learning. The sensor model 20 may be configured to model various sensors mounted within a vehicle for detecting information on a driving environment and driving state of the vehicle and may also provide information required according to an input from the controller model 30.

FIG. 5 is a diagram illustrating an example of a sensor model of a system for evaluating vehicle performance according to an exemplary embodiment of the present disclosure. As shown in FIG. 5, the sensor model 20 may include a recognition sensor model 21 for outputting information to be acquired by detecting a driving environment of a vehicle, and a vehicle behavior sensor model 22 for detecting and outputting information related to a behavior of a vehicle.

The recognition sensor model 21 may be a model like a camera (e.g., imaging device), a lidar, a radar, an infrared sensor, or the like, and may output a road curvature, a distance from a leading vehicle, a relative speed, or the like. The vehicle behavior sensor model 22 may output a detection value of information related to a vehicle behavior like a yaw sensor, an acceleration sensor, a lateral speed sensor, or a lateral acceleration sensor.

The sensor model 20 may be modeled to detect information required for vehicle control based on a driving environment scenario provided by the driving environment model 10 and may also be modeled to detect information required for vehicle control based on a modeling result related to a vehicle behavior output from the aforementioned dynamic model 50. The driving environment model 10 may be a model for storing a scenario of various driving environments of a vehicle for examining vehicle performance.

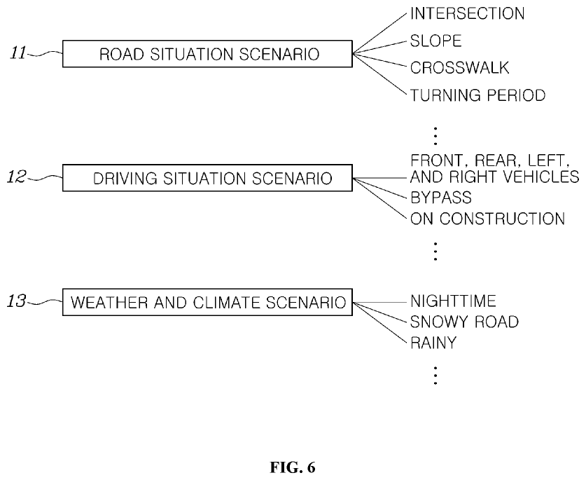

FIG. 6 is a diagram illustrating an example of a driving environment model of a system for evaluating vehicle performance according to an exemplary embodiment of the present disclosure. Referring to FIG. 6, a vehicle driving environment scenario modeled in the driving environment model 10 may broadly include a road situation scenario 11, a driving situation scenario 12, and a weather and climate scenario 13.

The road situation scenario 11 may store a scenario of a type of a road on which a vehicle is being driven, and may store a scenario of a type of road or gradient/slope of the road or a turning state (e.g., a curve along the road), such as an intersection, a slope, a crosswalk, or a turning period. The driving situation scenario 12 may store a scenario of a driving situation of the vehicle and may store a scenario of information on other vehicles positioned before, behind, right, and left the driving vehicle, information on a bypass, information on construction, or the like. The weather and climate scenario 13 may store the weather or climate or a day and night state when a vehicle is being driven and may store a scenario of night driving, driving on a snowy or wet road, or the like.

An operation mechanism of the system for evaluating vehicle performance according to an exemplary embodiment of the present disclosure as configured above will be described below.

First, the driving environment model 10 may select a scenario model for evaluating vehicle performance. In particular, the driving environment model 10 may configure a scenario model appropriate for an evaluation purpose such as the number of lanes of a road, the number of vehicles that are being driven on the road, a freezing state of the road, a type of the road (e.g., an asphalt road, an unpaved road, or the like), whether a vehicle rapidly cuts or drives in front of another vehicle, or a road curvature.

Further, the sensor model 20 may provide information to be detected by a sensor of an actual vehicle as a signal to be provided to the controller model 30 using information determined by the driving environment model 10. The sensor model 20 may output vehicle external information by the recognition sensor model 21 and may output driving vehicle information by the vehicle behavior sensor model 22. For example, the vehicle external information may include lane information (e.g., whether a lane is a solid line or a dotted line, or a lane interval) or curvature information, as captured by a sensor such as a camera, and a relative speed or a vehicle distance detected by a sensor such as a lidar. The vehicle behavior sensor model 22 may correspond to a yaw rate detected by a yaw sensor, a wheel speed of each wheel detected by a wheel speed sensor, and a steering angle detected by a steering angle sensor.

The sensor model 20 may receive vehicle behavior information output from the dynamic model 50 and may output a detection value of vehicle behavior information, to be detected therefrom. For example, the sensor model 20 may output a brake pedal signal detected by the brake pedal sensor model in the sensor model 20 and a detection value of a wheel speed of each wheel detected by the wheel speed sensor model at a time point at which the brake pedal signal is generated (e.g., the brake pedal is engaged).

Additionally, the controller model 30 may receive a signal that corresponds to a detection value output from the sensor model 20 and may generate and output a control signal output by a controller configured to operate various systems within a vehicle using the detection values. The controller model 30 may be configured by embodying substantially the same control logic as a controller applied to an actual vehicle or may be configured to output a similar control signal to a controller of an actual vehicle using a neural network circuit trained by machine learning, and may generate a control signal for operating each system of a vehicle using a signal provided from the sensor model 20 as a parameter. For example, the ABS controller model in the controller model 30 may receive a detection value of a wheel speed of each wheel from the sensor model 20 and may output a brake pressure control signal of each wheel that corresponds to the detection value.

The function system model 40 may then receive a control signal output from the controller model 30 and may provide an output for an operation of various systems of the vehicle, determined according to the control signal. For example, when receiving a brake pressure control signal of each wheel from the controller model 30, a brake system model in the function system model 40 may output a result value of each operation from the engine system model 41 for performing an engine throttle relevant operation based on a brake pressure of each wheel, the air management system model 42 for performing an auxiliary brake and air tank relevant operation based on a brake pressure of each wheel, the brake valve model 43 for adjusting a brake pressure based on a brake pressure of each wheel, and the front-wheel foundation model 44 and the rear-wheel foundation model 45, which are related to an operation of front-wheel foundation and rear-wheel foundation based on a brake pressure of each wheel.

Further, the dynamic model 50 may receive an output of the function system model 40 and may determine vehicle behavior characteristics based thereon. The dynamic model 50 may be a dynamic model for describing a behavior of an actual vehicle, may be configured based on a chassis characteristics model such as suspension hard point characteristics, spring/damper characteristics, or wheel alignment characteristic, and may output movement of the center of a weight of a vehicle and a behavior to front-rear-left-right sides of the vehicle.

The dynamic model 50 may visually animate and represent the determined vehicle behavior, and information regarding the vehicle behavior may be transmitted back to the sensor model 20 to enable the sensor model 20 to output a detection value obtained by detecting the vehicle behavior characteristics.

The aforementioned system for evaluating vehicle performance according to various exemplary embodiments of the present disclosure may be embodied by a computer system including a storage medium such as a processor or a memory. The models and a connection relationship thereof described in relation to exemplary embodiments disclosed in the specification may be directly embodied by hardware and software modules implemented by a processor, or a combination of the two thereof. The software module may be installed in a storage medium such as RAM, a flash memory, ROM, EPROM, EEPROM, register, a hard disk, a removable disk, or CD-ROM. An exemplary storage medium may be coupled to a processor, and the processor may read information from the storage medium and may write information on the storage medium. As another method, the storage medium may be integrated into the processor. The processor and the storage medium may be installed in an application specific integrated circuit (ASIC). The ASIC may also be installed in a user terminal. As another method, the processor and the storage medium may be installed as a separate component in the user terminal.

As described above, the system for evaluating vehicle performance according to an exemplary embodiment of the present disclosure may analyze various performances of a vehicle and may enhance performance through the analysis compared with a conventional art for evaluating vehicle performance dependent upon a document template by embodying substantially the same characteristics of an actual vehicle through modeling of a vehicle behavior from a vehicle driving environment.

In particular, a dynamic model may describe an actual behavior using output values of a vehicle system, which are output from a system model of the vehicle, and thus, it may be possible to describe and analyze the behavior of the vehicle in detail based on a reaction of each system. It may be possible to examine a reaction of each system depending on various control situations through a controller model that corresponds to a controller of the vehicle, and it may also be possible to predict and analyze a behavior of an actual vehicle based on a reaction of a system to a control signal output from the controller. A scenario for various road and traffic situations may be provided through a driving environment model, and thus it may be possible to examine an operation of a vehicle with respect to various situations without an actual driving test.

The system for evaluating vehicle performance may analyze various performances of a vehicle and may enhance performance through the analysis compared with a conventional art for simply evaluating vehicle performance dependent upon a document template by embodying substantially the same characteristics of an actual vehicle through modeling of a vehicle behavior from a vehicle driving environment. In particular, according to the system for evaluating vehicle performance, a dynamic model may describe an actual behavior using output values of a vehicle system, which are output from a system model of the vehicle, and thus, it may be possible to describe and analyze the behavior of the vehicle in detail based on a reaction of each system.

According to the system for evaluating vehicle performance, it may be possible to examine a reaction of each system depending on various control situations through a controller model that corresponds to a controller of the vehicle, and it may also be possible to predict and analyze a behavior of an actual vehicle based on a reaction of a system to a control signal output from the controller.

In addition, according to the system for evaluating vehicle performance, a scenario for various road and traffic situations may be provided via a driving environment model, and thus it may be possible to examine an operation of a vehicle with respect to various situations without an actual driving test. It will be appreciated by persons skilled in the art that that the effects that could be achieved with the present disclosure are not limited to what has been particularly described hereinabove and other advantages of the present disclosure will be more clearly understood from the detailed description.

Although the exemplary embodiments of the present disclosure have been described above with reference to the accompanying drawings, those skilled in the art will appreciate that the present disclosure may be implemented in various other embodiments without changing the technical ideas or features thereof.

What is claimed is:

1. A system for evaluating vehicle performance, comprising:
a function system model configured to model an operation of a function system of a vehicle, an operation of which is determined based on a control signal output from a controller within the vehicle; and
a dynamic model configured to model a behavior of the vehicle based on the operation of the function system model.

2. The system for evaluating vehicle performance of claim 1, further comprising:
a controller model configured to model a controller configured to output a control signal for operating the function system based on a detection value output from a sensor mounted within the vehicle,
wherein the control signal output from the controller model is provided as an input of the function system model.

3. The system for evaluating vehicle performance of claim 2, further comprising:
a sensor model configured to model a sensor mounted within the vehicle and to output a detection value obtained by detecting information related to a driving environment of the vehicle and a driving state of the vehicle,
wherein the detection value output from the sensor model is provided as an input of the controller model.

4. The system for evaluating vehicle performance of claim 3, further comprising:
a driving environment model configured to model and provide various scenarios for a driving environment of the vehicle,
wherein the scenario provided by the driving environment model is provided as an input of the sensor model.

5. The system for evaluating vehicle performance of claim 1, wherein the dynamic model includes:
a dynamic load movement model configured to model dynamic load movement characteristics of the vehicle, which is determined based on information including at least one of the a weight, a center distance, an axle weight, and a center of weight of the vehicle and operation relevant information of a vehicle system, input from the function system model;
a tire slip model configured to model slip characteristics of a tire based on the dynamic load movement characteristics of the vehicle; and
a suspension model configured to model characteristics of a spring or damper depending on the dynamic load movement characteristics and hard point characteristics of a suspension.

6. The system for evaluating vehicle performance of claim 2, wherein the controller model is configured based on control logic of a controller applied to an actual vehicle.

7. The system for evaluating vehicle performance of claim 2, wherein the controller model is configured in a neural network circuit trained via machine learning based on an input and output signal of an actual vehicle.

8. The system for evaluating vehicle performance of claim 3, wherein the sensor model includes a recognition sensor model configured to output information to be acquired by detecting the driving environment of the vehicle, and a vehicle behavior sensor model configured to detect and output information related to the behavior of the vehicle.

9. The system for evaluating vehicle performance of claim 8, wherein the sensor model receives the information related to the behavior of the vehicle and provides a detection value detected from the information related to the behavior of the vehicle to the controller model.

10. A system for evaluating vehicle performance for copying a behavior of an actual vehicle, comprising:
a driving environment model configured to model and provide various scenarios for a driving environment of a vehicle;
a sensor model configured to model a sensor mounted within the actual vehicle and to output a detection value obtained by detecting information related to the driving environment of the vehicle, provided by the driving environment model;
a controller model configured to model a controller mounted within the actual vehicle and to output a control signal for operating a function system included in the vehicle based on the detection value provided by the sensor model;
a function system model configured to model the function system included in the actual vehicle and to provide information regarding an output of the function system of the vehicle, an operation of which is determined based on the control signal output from the controller model; and
a dynamic model configured to derive vehicle behavior information based on the output provided from the function system model.

11. The system for evaluating vehicle performance of claim 9, wherein the sensor model receives vehicle behavior information derived by the dynamic model and provides a detection value obtained by detecting information related to driving characteristics of the vehicle based on the vehicle behavior information to the controller model.

12. The system for evaluating vehicle performance of claim 9, wherein the dynamic model includes:
a dynamic load movement model configured to model dynamic load movement characteristics of the vehicle, which is determined based on information including at least one of a weight, a center distance, an axle weight, and a center of weight of the vehicle and an operation relevant information of a vehicle system, input from the function system model;
a tire slip model configured to model slip characteristics of a vehicle tire based on the dynamic load movement characteristics of the vehicle; and
a suspension model configured to model characteristics of a spring or damper based on the dynamic load movement characteristics of the vehicle and hard point characteristics of a suspension.

13. The system for evaluating vehicle performance of claim 9, wherein the controller model is configured based on control logic of a controller applied to an actual vehicle.

14. The system for evaluating vehicle performance of claim 9, wherein the controller model is configured in a neural network circuit trained via machine learning based on an input and output signal of an actual vehicle.

15. The system for evaluating vehicle performance of claim 9, wherein the sensor model includes a recognition sensor model configured to output information to be acquired by detecting the driving environment of the vehicle, and a vehicle behavior sensor model configured to detect and output information related to the behavior of the vehicle.
